(19) United States
(12) Patent Application Publication
(10) Pub. No.: US 2013/0009629 A1
(43) Pub. Date: Jan. 10, 2013

(54) DETECTION APPARATUS FOR CIRCUIT BOARD

(75) Inventors: ZHAN-YANG LI, Shenzhen City, Guangdong Province (CN); WEN-HU LU, Shenzhen City, Guangdong Province (CN); PO-WEN CHIU, Tu-Cheng, New Taipei (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/454,169

(22) Filed: Apr. 24, 2012

(30) Foreign Application Priority Data
Jul. 8, 2011 (CN) 201110190558.7

(51) Int. Cl. G01R 1/04

(52) U.S. Cl. 324/156

(57) ABSTRACT

A detection apparatus comprises a first signal transmission line, a second signal transmission line, a first conducting member, a second conducting member and a mounting bracket. A first terminal of the first signal transmission line is electrically connected to a circuit board for receiving first output signals. A second terminal of the first signal transmission line is electrically connected to a first terminal of the first conducting member. A first terminal of the second signal transmission line is electrically connected to the circuit board for receiving second output signals. A second terminal of the second signal transmission line is electrically connected to a first terminal of the second conducting member. The first conducting member and the second conducting member are mounted on the mounting bracket. Each of a second terminal of the first conducting member and a second terminal of the second conducting member extends out of the mounting bracket.

### BACKGROUND

1. Technical Field

The present disclosure relates to a detection apparatus for detecting output signals of a circuit board in an electronic device enclosure.

2. Description of Related Art

A typical electronic device may include an electronic device enclosure and a circuit board fastened in the electronic device enclosure. The circuit board is usually sealed in the electronic device enclosure. It may be difficult for a user to access the circuit board from out of the electronic device enclosure. Thus, the circuit board may not be repaired quickly when the circuit board malfunctions.

Therefore there is a need for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a detection apparatus for a circuit board.

FIG. 2 is an isometric view of a first conducting member of the detection apparatus of FIG. 1.

FIG. 3 is an isometric view of a second conducting member of the detection apparatus of FIG. 1.

FIG. 4 is an isometric view of a mounting bracket of the detection apparatus of FIG. 1.

FIG. 5 is an assembly view of the detection apparatus of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

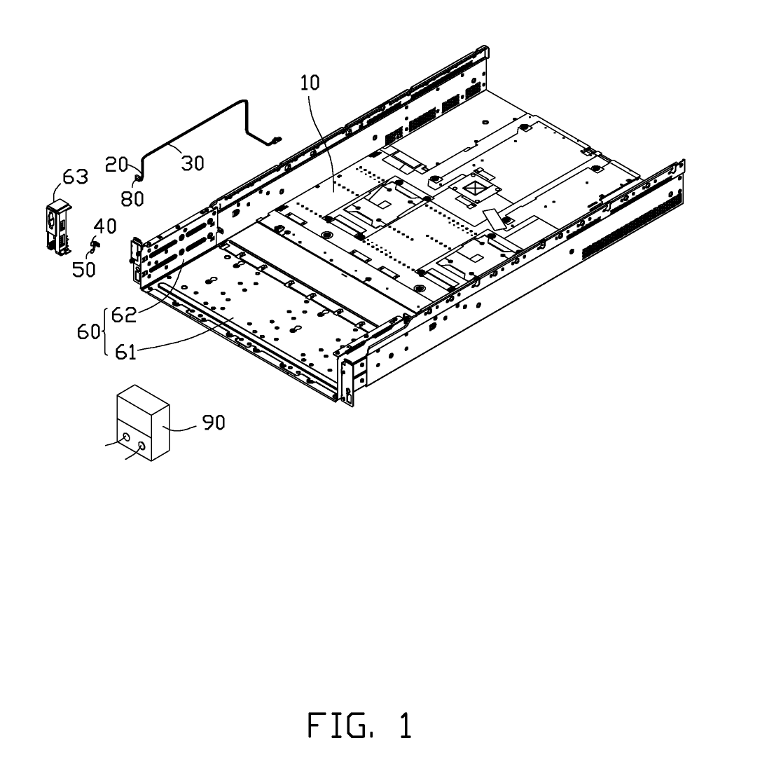

FIG. 1, is a detection apparatus configured for detecting output signals of a circuit board 10 in an electronic device enclosure 60. The detection apparatus in accordance with an embodiment, includes a first signal transmission line 20, a second signal transmission line 30, a first conducting member 40 and a second conducting member 50. The electronic device enclosure 60 includes a base plate 61 and a side plate 62. The circuit board 10 is mounted on the base plate 61. A mounting bracket 63 is mounted on the side plate 62.

A first terminal of the first signal transmission line 20 is electrically connected to the circuit board 10 for receiving first output signals. A second terminal of the first signal transmission line 20 is electrically connected to a first terminal of the first conducting member 40. A first terminal of the second signal transmission line 30 is electrically connected to the circuit board 10 for receiving second output signals. A second terminal of the second signal transmission line 30 is electrically connected to a first terminal of the second conducting member 50. Each of the first conducting member 40 and the second conducting member 50 is mounted on the mounting bracket 63. Each of a second terminal of the first conducting member 40 and a second terminal of the second conducting member 50 extends out of the mounting bracket 63 and electrically connected to a display 90. In one embodiment, the first signal transmission line 20 is a data line, and the second signal transmission line 30 is a ground line. The first conducting member 40 and the second conducting member 50 are electrically connected respectively to the first signal transmission line 20 and the second signal transmission line 30 via a connector 80 mounted on the side plate 62.

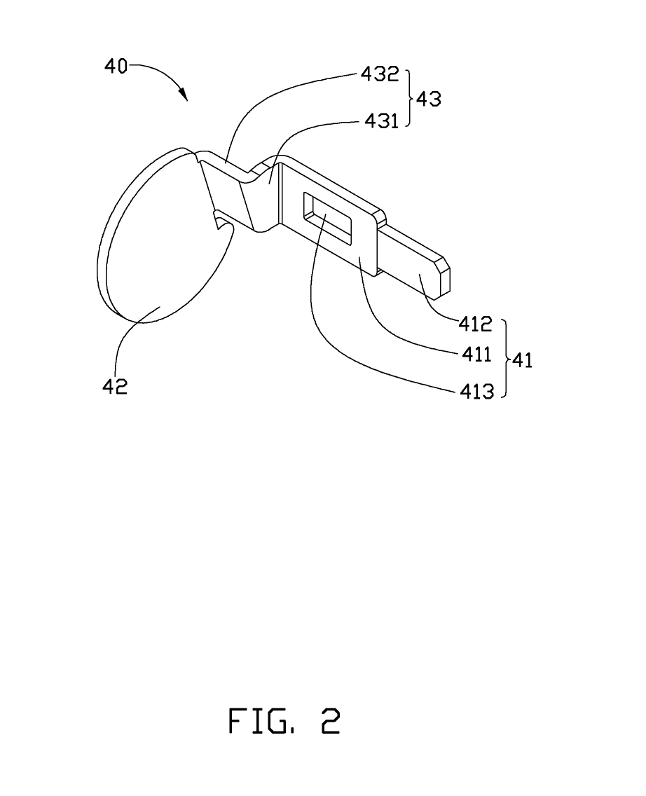

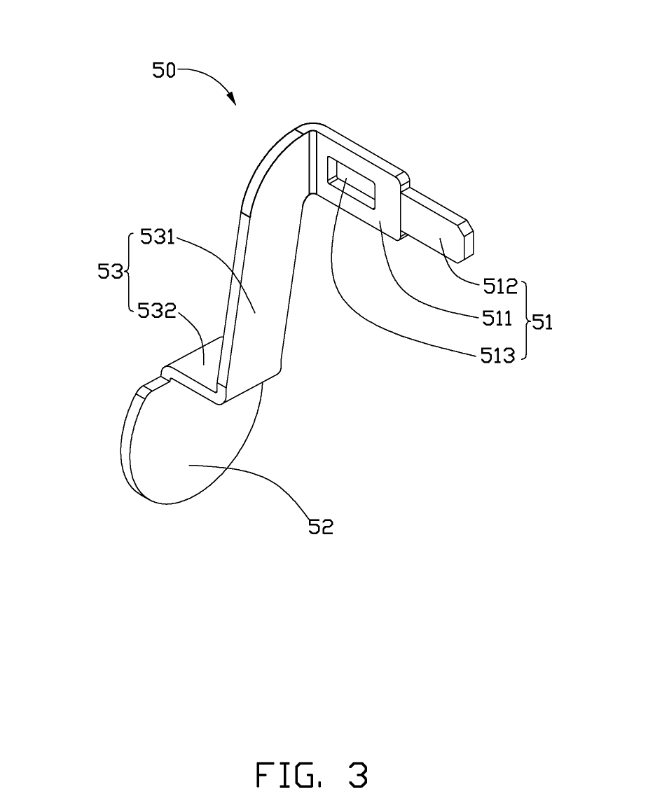

FIGS. 2 and 3, show the first conducting member 40 including a first conducting portion 41, a crown shaped first contacting portion 42, and a first connection portion 43 connected between the first conducting portion 41 and the first contacting portion 42. The first conducting portion 41 includes a first mounting slice 411 and a first insertion slice 412 extending from a distal end of the first mounting slice 411. A long first mounting hole 413 is defined in the first mounting slice 411. The first connection portion 43 includes a trapezium shaped first connecting slice 431 and a rectangular second connecting slice 432 bent from a distal end of the first connecting slice 431. The first connecting slice 431 is connected to the first mounting slice 411. The second connecting slice 432 is connected to first contacting portion 42. In one embodiment, a width of the first mounting slice 411 is greater than that of the first insertion slice 412.

The second conducting member 50 includes a second conducting portion 51, a crown shaped second contacting portion 52, and a second connection portion 53 connected between the second conducting portion 51 and the second contacting portion 52. The second conducting portion 51 includes a second mounting slice 511 and a second insertion slice 512 extends from a distal end of the second mounting slice 511. A long second mounting hole 513 is defined in the second mounting slice 511. The second connection portion 53 includes a trapezium shaped third connecting slice 531 and a rectangular fourth connecting slice 532 bent from a distal end of the third connecting slice 531. The third connecting slice 531 is connected to the second mounting slice 511. The fourth connecting slice 532 is connected to second contacting portion 52. In one embodiment, an extending direction of the third connecting slice 531 is perpendicular to that of the second connecting slice 432. A length of the third connecting slice 531 is greater than that of the second connecting slice 432. The first conducting member 40 and the second conducting member 50 are made of metal material.

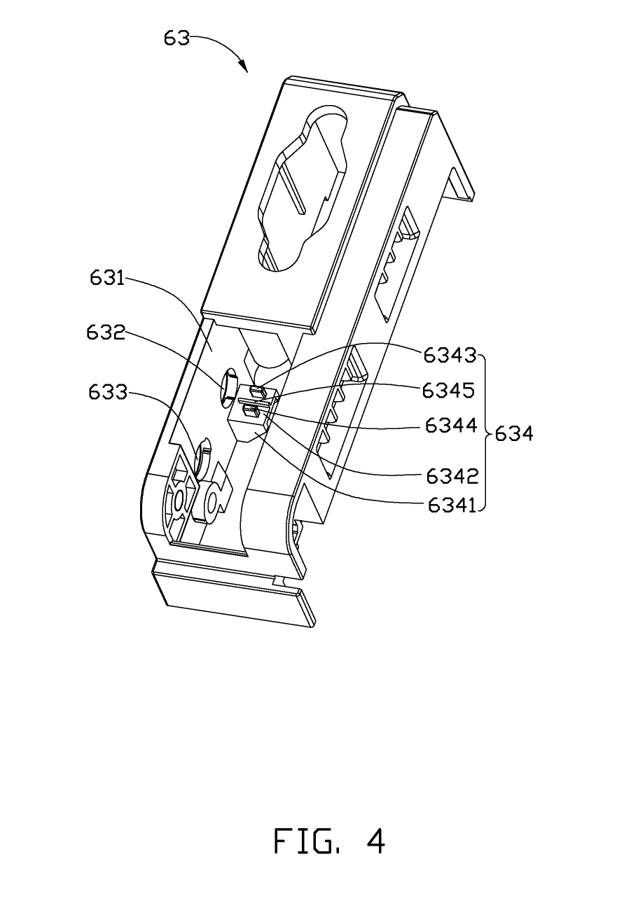

FIG. 4, shows the mounting bracket 63 including a mounting plate 631 perpendicular to the side plate 62. A first through hole 632 is defined in the mounting plate 631 corresponding to the first contacting portion 42. A second through hole 633 is defined in the mounting plate 631 corresponding to the second contacting portion 52.

A supporting portion 634 extends from the mounting plate 631 adjacent to the first through hole 632. The supporting portion 634 includes two trapezium shaped supporting slices 6341 extending from the mounting plate 631 and a rectangular fifth connecting slice 6342 connected between the two supporting slices 6341. A first protrusion portion 6343 extends uprightly from the fifth connecting slice 6342 corresponding to the first mounting hole 413. A second protrusion portion 6344 extends uprightly from the fifth connecting slice 6342 corresponding to the second mounting hole 513. A third protrusion portion 6345 extends uprightly from the fifth connecting slice 6342 between the first protrusion portion 6343 and the second protrusion portion 6344. The third protrusion portion 6345 is configured to separate the first mounting slice 411 and the second mounting slice 511.

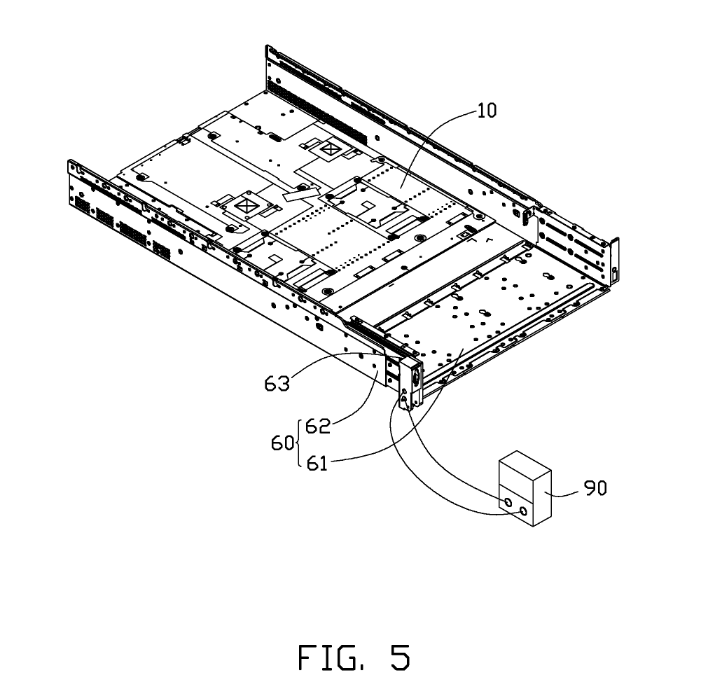

FIG. 5, shows in assembly, the mounting bracket 63 is mounted on the side plate 62. The first insertion slice 412 and the second insertion slice 512 are respectively inserted in the connector 80 and electrically connected to the connector 80. The first protrusion portion 6343 passes through the first mounting hole 413. The second protrusion portion 6344 passes through the second mounting hole 513. The first contacting portion 42 is received in the first through hole 632. The second contacting portion 52 is received in the second through hole 633. The first conducting member 40 and the second conducting member 50 are mounted between the side plate 62 and the mounting plate 631. Thus, the display 90 is electrically connected to the first contacting portion 42 and the second contacting portion 52 from out of the mounting plate 631 to detect first output signals and second output signals of the circuit board 10. It is easy for a user to access data on the circuit board 10 from out of the electronic device enclosure 60. The circuit board 10 can be repaired quickly when errors occur.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A detection apparatus, comprising:
a first signal transmission line, a second signal transmission line, a first conducting member, a second conducting member and a mounting bracket; a first terminal of the first signal transmission line is electrically connected to a circuit board for receiving first output signals; a second terminal of the first signal transmission line is electrically connected to a first terminal of the first conducting member; a first terminal of the second signal transmission line is electrically connected to the circuit board for receiving second output signals; a second terminal of the second signal transmission line is electrically connected to a first terminal of the second conducting member; each of the first conducting member and the second conducting member is mounted on the mounting bracket; and each of a second terminal of the first conducting member and a second terminal of the second conducting member extends out of the mounting bracket.

2. The detection apparatus of claim 1, wherein the mounting bracket comprises a mounting plate; a first through hole, corresponding to the first conducting member, is defined in the mounting plate; a second through hole, corresponding to the second conducting member, is defined in the mounting plate; a supporting portion extends from the mounting plate adjacent to the first through hole; the first terminal of the first conducting member and the first terminal of the second conducting member are fixed on the supporting portion; the second terminal of the first conducting member extends out of the mounting bracket via the first through hole; and the second terminal of the second conducting member extends out of the mounting bracket via the second through hole.

3. The detection apparatus of claim 2, wherein the first conducting member comprises a first conducting portion and a first contacting portion; a first mounting hole is defined in the first conducting portion; the supporting portion comprises two supporting slices extending from the mounting plate and a fifth connecting slice connected between the two supporting slices; a first protrusion portion extends from the fifth connecting slice; and when the first conducting member is mounted on the mounting bracket, the first protrusion portion passes through the first mounting hole, and the first contacting portion is received in the first through hole.

4. The detection apparatus of claim 3, wherein the first conducting portion comprises a first mounting slice and a first insertion slice extends from a distal end of the first mounting slice; the first mounting hole is defined in the first mounting slice; and a width of the first mounting slice is greater than a width of the first insertion slice.

5. The detection apparatus of claim 4, wherein the first conducting member further comprises a first connection portion connected between the first conducting portion and the first contacting portion; the first connection portion comprises a first connecting slice and a second connecting slice bent from a distal end of the first connecting slice; the first connecting slice is connected to the first mounting slice; and the second connecting slice is connected to first contacting portion.

6. The detection apparatus of claim 5, wherein the second conducting member comprises a second conducting portion and a second contacting portion; a second mounting hole is defined in the second conducting portion; a second protrusion portion extends from the fifth connecting slice; and when the second conducting member is mounted on the mounting bracket, the second protrusion portion passes through the second mounting hole, and the second contacting portion is received in the second through hole.

7. The detection apparatus of claim 6, wherein the second conducting portion comprises a second mounting slice and a second insertion slice extends from a distal end of the second mounting slice; the second mounting hole is defined in the second mounting slice; and a width of the second mounting slice is greater than a width of the second insertion slice.

8. The detection apparatus of claim 7, wherein the second conducting member further comprises a second connection portion connected between the second conducting portion and the second contacting portion; the second connection portion comprises a third connecting slice and a fourth connecting slice bent from a distal end of the third connecting slice; the third connecting slice is connected to the second mounting slice; and the fourth connecting slice is connected to second contacting portion.

9. The detection apparatus of claim 8, wherein an extending direction of the third connecting slice is perpendicular to an extending direction of the second connecting slice; a length of the third connecting slice is greater than a length of the second connecting slice; a third protrusion portion extends from the fifth connecting slice between the first protrusion portion and the second protrusion portion; and the third protrusion portion is configured to separate the first mounting slice and the second mounting slice.

10. The detection apparatus of claim 9 comprising an electronic device enclosure, wherein the circuit board and the mounting bracket are mounted on the electronic device enclosure; the electronic device enclosure comprises a base plate, a side plate, and a connector mounted on the side plate; the circuit board is mounted on the base plate; the mounting bracket is mounted on the side plate; each of the second terminal of the first conducting member and the second terminal of the second conducting member extends out of the mounting bracket and is electrically connected to a display; and the first conducting member and the second conducting member are electrically connected to the first signal transmission line and the second signal transmission line respectively by the connector.

11. A detection apparatus for detecting output signals of a circuit board, comprising:
an electronic device enclosure; a first signal transmission line, a second signal transmission line, a first conducting member, a second conducting member and a mounting bracket; the electronic device enclosure comprises a base plate, a side plate, and a connector mounted on the side plate; a first terminal of the first signal transmission line is electrically connected to the circuit board for receiving first output signals; a second terminal of the first signal transmission line is electrically connected to a first terminal of the first conducting member by the connector; a first terminal of the second signal transmission line is electrically connected to the circuit board for receiving second output signals; a second terminal of the second signal transmission line is electrically connected to a first terminal of the second conducting member by the connector; each of the first conducting member and the second conducting member is mounted on the mounting bracket; and each of a second terminal of the first conducting member and a second terminal of the second conducting member extends out of the mounting bracket.

12. The detection apparatus of claim 11, wherein the mounting bracket comprises a mounting plate; a first through hole, corresponding to the first conducting member, is defined in the mounting plate; a second through hole, corresponding to the second conducting member, is defined in the mounting plate; a supporting portion extends from the mounting plate adjacent to the first through hole; the first terminal of the first conducting member and the first terminal of the second conducting member are fixed on the supporting portion; the second terminal of the first conducting member extends out of the mounting bracket via the first through hole; and the second terminal of the second conducting member extends out of the mounting bracket via the second through hole.

13. The detection apparatus of claim 12, wherein the first conducting member comprises a first conducting portion and a first contacting portion; a first mounting hole is defined in the first conducting portion; the supporting portion comprises two supporting slices extending from the mounting plate and a fifth connecting slice connected between the two supporting slices; a first protrusion portion extends from the fifth connecting slice; and when the first conducting member is mounted on the mounting bracket, the first protrusion portion passes through the first mounting hole, and the first contacting portion is received in the first through hole.

14. The detection apparatus of claim 13, wherein the first conducting portion comprises a first mounting slice and a first insertion slice extends from a distal end of the first mounting slice; the first mounting hole is defined in the first mounting slice; and a width of the first mounting slice is greater than a width of the first insertion slice.

15. The detection apparatus of claim 14, wherein the first conducting member further comprises a first connection portion connected between the first conducting portion and the first contacting portion; the first connection portion comprises a first connecting slice and a second connecting slice bent from a distal end of the first connecting slice; the first connecting slice is connected to the first mounting slice; and the second connecting slice is connected to first contacting portion.

16. The detection apparatus of claim 15, wherein the second conducting member comprises a second conducting portion and a second contacting portion; a second mounting hole is defined in the second conducting portion; a second protrusion portion extends from the fifth connecting slice; and when the second conducting member is mounted on the mounting bracket, the second protrusion portion passes through the second mounting hole, and the second contacting portion is received in the second through hole.

17. The detection apparatus of claim 16, wherein the second conducting portion comprises a second mounting slice and a second insertion slice extends from a distal end of the second mounting slice; the second mounting hole is defined in the second mounting slice; and a width of the second mounting slice is greater than a width of the second insertion slice.

18. The detection apparatus of claim 17, wherein the second conducting member further comprises a second connection portion connected between the second conducting portion and the second contacting portion; the second connection portion comprises a third connecting slice and a fourth connecting slice bent from a distal end of the third connecting slice; the third connecting slice is connected to the second mounting slice; and the fourth connecting slice is connected to second contacting portion.

19. The detection apparatus of claim 18, wherein an extending direction of the third connecting slice is perpendicular to an extending direction of the second connecting slice; a length of the third connecting slice is greater than a length of the second connecting slice; a third protrusion portion extends from the fifth connecting slice between the first protrusion portion and the second protrusion portion; and the third protrusion portion is configured to separate the first mounting slice and the second mounting slice.

20. The detection apparatus of claim 19, wherein each of the circuit board and the mounting bracket is mounted on the electronic device enclosure; the circuit board is mounted on the base plate; the mounting bracket is mounted on the side plate; and each of the second terminal of the first conducting member and the second terminal of the second conducting member extends out of the mounting bracket and is electrically connected to a display.
